(19) United States
(12) Patent Application Publication
(10) Pub. No.: US 2002/0063606 A1
(43) Pub. Date: May 30, 2002

(54) Receiver circuit

(75) Inventor: Paulus Thomas Maria van Zeijl, Dasstraat (NL)

Correspondence Address: Stanley R. Moore, Esq., Jenkens and Gilchrist, P.C., 3200 Fountain Place, 1445 Ross Avenue, Dallas, TX, 75202, US

(73) Assignee: Telefonaktiebolaget L M Ericsson

(21) Appl. No.: 09/730,452

(22) Filed: Dec. 5, 2000

(30) Foreign Application Priority Data
Dec. 9, 1999 (GB) 9929182.5

(51) Int. Cl. H03B 1/00; H04L 27/10; H04B 1/40; H03C 1/60; H04L 27/04; H04L 27/12; H04L 27/20

(52) U.S. Cl. 331/74; 375/272; 455/86; 332/170; 375/295

(57) ABSTRACT

An image reject circuit comprises a local oscillator 26 for producing a local oscillator signal. A tunable phase shifting network 29 has inputs 1, 3 for receiving the local oscillator signal and producing an output in-phase (I) signal 13, 25 and an output quadrature (Q) signal 15, 27. A first amplitude detector 33 determines the amplitude of the output I signal, while a second amplitude detector 35 determines the amplitude of the output Q signal. A comparator 37 determines the difference between the amplitudes of the output I and Q signals, to produce a tuning signal for tuning the phase shifting network 29 to bring the difference between the amplitudes of the output I and Q signals towards a desired level. Preferably, the tunable phase shifting network 29 (shown in FIG. 4) comprises a combination of tunable capacitive, resistive and inductive elements.

### FIELD OF THE INVENTION

The invention relates to an image reject circuit and to a method of rejecting images.

### BACKGROUND OF THE INVENTION

Transceivers utilise frequency mixers for converting high frequency signals to low frequency signals or vice versa. Such conversion is required, for example, to convert a signal from a desired frequency to an intermediate frequency (IF), an intermediate frequency (IF) being the difference between an incoming carrier frequency and a local-oscillator (LO) frequency.

When converting frequencies in this manner an undesired image frequency is generated, and consequently, various methods have been developed to effectively eliminate the image signal.

Until recently, off-chip filters have been used to provide image rejection. However, the physical size of the components involved means that such circuits are not suited for implementation on an integrated circuit.

An alternative approach to filtering the image signal is to cancel the image signal. Image cancellation or rejection mixers consist, for example, of two mixers, driven by two local-oscillator signals which have a 90° phase difference, and an IF phase shifter such that the two IF signals are again phase shifted (usually 45° in one branch and 135° in the second branch) and a combiner or summing circuit. The result is that when the signals are summed, the desired signal components are added together while the undesired image signal components are cancelled, resulting in a receiver having image rejection.

Image rejection circuits such as these rely on the accurate values of components. However, nominally identical components vary due to temperature variations, process spread and/or ageing and, as a consequence, calibration is therefore required during manufacture. For example, this can involve taking measurements during the manufacturing stage, and adjusting programmable resistors and/or capacitors accordingly.

As well as adding to the manufacturing process, once programmed the circuits are fixed, and cannot adapt to changes which may occur during use or ageing.

Another known method of improving image rejection is to use an inaccurate 90° phase shifter in the local oscillator path, which is corrected by an RC-polyphase correction network. However, to obtain an image rejection of about 50-60 dB using this type of solution, the components within the respecive devices must be matched to within 0.1%. Since mismatch usually scales inversely with silicon area, a large silicon area is therefore required to obtain an acceptable image rejection. A large silicon area impies large parasitic capacitances to the substrate, which in turn compromises high frequency performance. Also, the integrated circuit layout is very critical, as any parasitic capacitance or resistance degrades image rejection.

In addition to the disadvantages mentioned above, improving image rejection in the IF path will have limited effect unless corresponding steps are taken to improve image rejection in the LO path.

Known circuits for realising phase-shifters are shown in FIGS. 1 and 2 respectively, in which FIG. 1 uses an all-pass phase shifter and FIG. 2 uses a high-pass/low-pass phase shifter. Further known solutions use inductors to realise the phase shifter in the LO path. However, inductors are large and thus not suited for implementation in an integrated circuit, (since two inductors of approximately 300 μm×300 μm are required).

FIG. 1 shows a conventional all-pass phase shifter in which the input signal is connected to terminals 1, 3 which are connected across a bridge formed by resistors 5, 7 and capacitors 9, 11. Input signal 1 is connected to the junction of resistor 5 with capacitor 11, while the input signal 3 is connected to the junction of resistor 7 with capacitor 9. The balanced output signal 13 and signal 15 are taken respectively from the junction of resistor 7 with capacitor 11, and the junction of resistor 5 with capacitor 9. The output signals 13, 15 are phase shifted relative to the input signals 1, 3 by an amount determined by the values of the resistors and capacitors.

A first part of FIG. 1 with R=600Ω and C-1 pF, (f=100 MHZ), gives a balanced I signal with, phase shifted by 45° from the input signal, while a second part with R=3840Ω and C=1 pF, (f=100 MHZ), gives the Q signal, phase shifted by 135° from the input signal. The phase difference between the I and Q signals is then 90°.

Ideally, the all-pass phase shifter described above should have a flat amplitude response over all frequencies. However, the impedance levels of the I and Q branches are significantly different, which makes realisation of the flat amplitude difficult in practice. The phase shift equals 2*arctan(ωRC), and is usually made 45° in the I branch and 135° in the Q branch. The phase shift is only optimal at one frequency. Thus, this all-pass phase shifter does not give sufficient performance for obtaining an image rejection of 40 dB or more, and a wide bandwidth, in the presence of process spread (for example from wafer to wafer), and mismatch (for example between components on the same wafer).

As mentioned above, FIG. 2 shows another known phase shifter for the LO path, and relates to a high-pass/low-pass phase shifter. Basically, this phase shifter comprises two all-pass phase shifters of FIG. 1 connected together as shown, using a second bridge consisting of resistors 17, 19 and capacitors 21, 23 connected to the first bridge. The input signal 1 is connected to the junction resistor 5 with capacitor 11, while the input signal 3 is connected to the junction of resistor 19 with capacitor 21. Unlike FIG. 1, the high-pass/low-pass phase shifter has a correct phase shift of 90° over all frequencies. This phase shifter has the advantage that the impedance in the I and Q branches are the same. The amplitude, however, will vary with frequency. Limiters are commonly used to lower the amplitude errors, but exhibit amplitude-to-phase conversions, thus generating phase errors from the amplitude errors. For this reason, the use of high-pass/low-pass phase shifters does not allow the mixing circuits to fulfill the requirement of image rejection.

The aim of the present invention is to provide an image rejection circuit which overcomes the disadvantages mentioned above.

### SUMMARY OF THE INVENTION

According to a first aspect of the present invention, there is provided an image reject circuit comprising:

a local oscillator for producing a local oscillator signal;

a tunable phase shifting network for receiving the local oscillator signal and producing an output in-phase (I) signal and an output quadrature (Q) signal;

a first amplitude detector for determining the amplitude of the output I signal;

a second amplitude detector for determining the amplitude of the output Q signal; and,

means for determining the difference between the amplitudes of the output I and Q signals, to produce a tuning signal for tuning the phase shifting network to bring the difference between the amplitudes of the output I and Q signals towards a desired level.

According to another aspect of the present invention, there is provided a method of rejecting an image signal, the method comprising the steps of a local oscillator for producing a local oscillator signal, and a tunable phase shifting network for receiving the local oscillator signal and producing an output in-phase (I) signal and an output quadrature (Q) signal, the method comprising the steps of;

determining the amplitude of the output I signal;

determining the amplitude of the output Q signal;

determining the difference between the amplitudes of the output I and Q signals, to produce a tuning signal; and,

using the tuning signal to tune the phase shifting network to bring the difference between the amplitudes of the output I and Q signals towards a desired level.

According to another aspect of the present invention, there is provided a tunable phase shifting network for use in an image reject circuit, the tunable phase shifting network comprising:

first and second input terminals for receiving an input signal;

a first phase shifting circuit connected between the first input terminal and a voltage reference;

a second phase shifting circuit connected between the voltage reference and the second input terminal;

wherein each phase shifting circuit comprises:

first and second parallel arms connected between the respective input terminal and the voltage reference;

the first arm comprising a resistive element connected in series with a capacitive element;

the second arm comprising a capacitive element connected in series with a resistive element; and,

I and Q output lines being connected to respective junctions between the series connected resistive element and capacitive element; and,

wherein the phase shifting network further comprises a tuning input for receiving a tuning signal for adjusting an RC time constant of the phase shifting network.

### BRIEF DESCRIPTION OF THE DRAWINGS

For a better understanding of the present invention, and to show more clearly how it may be carried into effect, reference will now be made, by way of example, to the accompanying drawings, in which:—

FIG. 1 shows a conventional all-pass phase shifter;

FIG. 2 shows a conventional high-pass/low-pass phase shifter;

FIG. 3 shows an image rejection circuit according to a first aspect of the present invention;

FIG. 4 shows a tunable high-pass/low-pass phase shifter for use in FIG. 3, according to a second aspect of the present invention;

FIG. 5 shows a known amplitude detector for use in FIG. 3;

FIG. 6 shows another known amplitude detector for use in FIG. 3;

FIGS. 7a-7d show the response of an RC phase shifter according to the prior art; and,

FIGS. 8a-8d show the response of an RC phase shifter according to the preferred embodiment of the present invention.

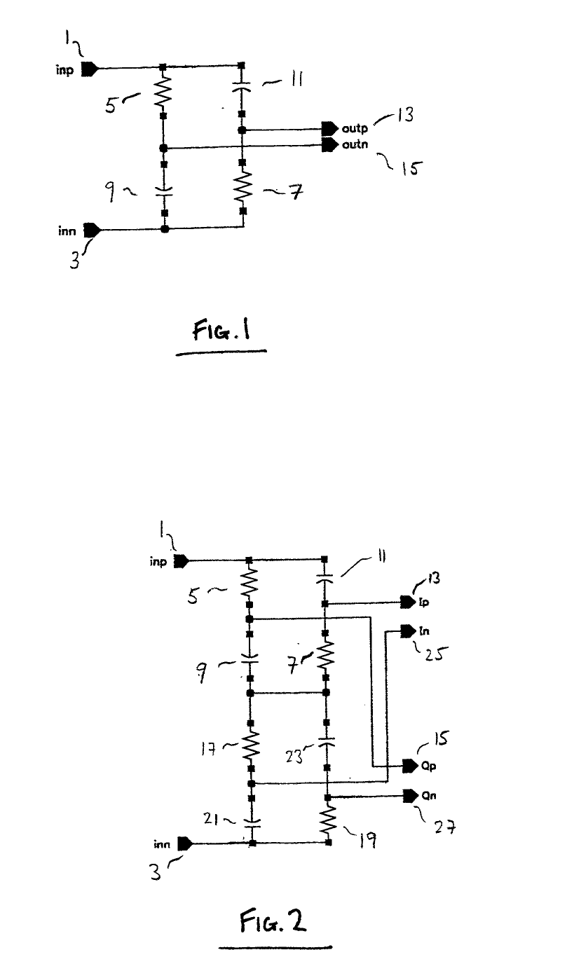

### DETAILED DESCRIPTION OF A PREFERRED EMBODIMENT OF THE PRESENT INVENTION

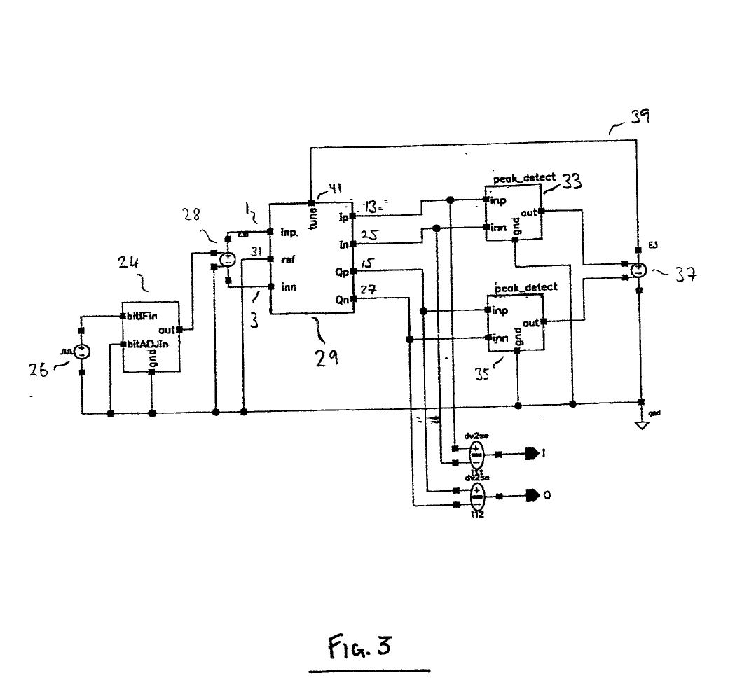

FIG. 3 shows a schematic diagram of an image rejection circuit according to the present invention. A voltage controlled oscillator 26 generates a LO signal, the frequency of which is dictated by circuit 24. The output of circuit 24 is connected to a voltage follower 28, which provides a balanced input signal 1, 3. Alternatively, in practice, items 24, 26 and 28 may be replaced by an oscillator/PLL circuit.

An RC tunable phase shifter 29 has first and second inputs for receiving the input signal 1, 3. It also receives a reference signal 31 which is connected, for example, to ground. The phase shifter 29 outputs complementary I and Q signals 13, 25 and 15, 27 respectively.

The I output signals 13, 25 are connected to a first peak or amplitude detector 33 which determines the amplitude of the I signal. The Q output signals 15, 27 are connected to a second peak or amplitude detector 35 which determines the amplitude of the Q signal. The outputs of the first and second peak detectors 33 and 35 are compared in a comparator 37, which produces a difference signal, or tuning signal 39 based on the difference between the amplitudes of the I and Q signals. The tuning signal 39 is fed back to the “tune” input 41 of the RC phase shifter 29, and is used to tune the RC phase shifter as described below with reference to FIG. 4.

Thus, in use, as the frequency of the input signal changes, say from 2.0 to 3.4 GHz, the amplitudes of the I and Q signals will change accordingly. The change in amplitudes is detected by each of the peak detectors 33, 35, thereby causing the tuning signal 39 to change. The tuning signal 39 is fed back to the RC phase shifter 29, which tunes the phase shifter such that the amplitudes of the I and Q signals become substantially equal once more, thereby maintaining optimum image rejection.

FIG. 4 shows the tunable RC phase shifter of FIG. 3 in greater detail, in accordance with a second aspect of the invention. The tunable RC phase shifter 29 is similar to the phase shifter of FIG. 2 in that it basically comprises two all-pass phase shifters connected together. However, the capacitors 9, 11, 21 and 23 have respectively been replaced by junction diodes 43, 45, 47 and 49. The difference signal or tuning signal 39 is connected to opposite ends of the phase shifter via resistors 51 and 53. Preferably, capacitor 55, 57, 59, 61 are provided in series with each of the output terminals 13, 15, 25 and 27 respectively, for minimising of the interaction with the remaining circuitry.

The junction diodes 43, 45, 47, 49 function in a similar way to varactor diodes, such that varying the DC voltage across the diodes causes the capacitance of the diodes to be changed,, thus enabling the phase shifter to be tuned. The tuning signal 39 is the difference between the amplitudes of the I and Q signals, which has been fed back from the comparator 37 as described in FIG. 3. Thus, the tunable RC phase shifter 29 can continually and automatically compensate for differences in amplitude between the I and Q signals which may have been caused by, for example, variation of components, or variation introduced by ageing or temperature fluctuations.

The embodiment described above tunes the phase shifter by varying the capacitance (i.e. by varying the voltage across the junction diodes 43, 45, 47 and 49). Alternatively, the phase shifter may be tuned by varying the resistance of the resistors 5, 7, 17 and 19, for example by operating a MOSFET in its triode region, such that it functions as a voltage dependent resistor. In such an embodiment, the gate of the MOSFET is connected to the tuning signal, and the drain and source are connected to the respective resistor connections.

Thus, the RC time constant may be changed by either varying the capacitance alone, varying the resistance alone, or varying a combination of the capacitance value and the resistance value.

Alternatively, either the resistive elements or the capacitive elements described above may be replaced by inductive elements, such that the time constant can be varied by changing the LC or RL time constants respectively.

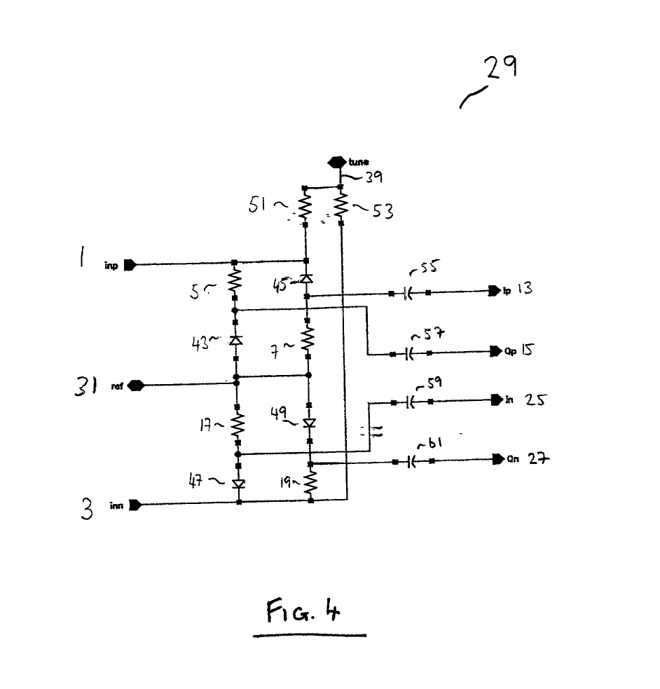

FIG. 5 shows a known peak detecting circuit for measuring the amplitude of the I and Q signals. The input signal is connected to the first terminal of a capacitor 63 via a series connected resistor 65 and forward polarity diode 67. The capacitor 63 stores the peak amplitude of the input signal, which is made available at the output terminal. This type of circuit is particularly suited to high frequency applications.

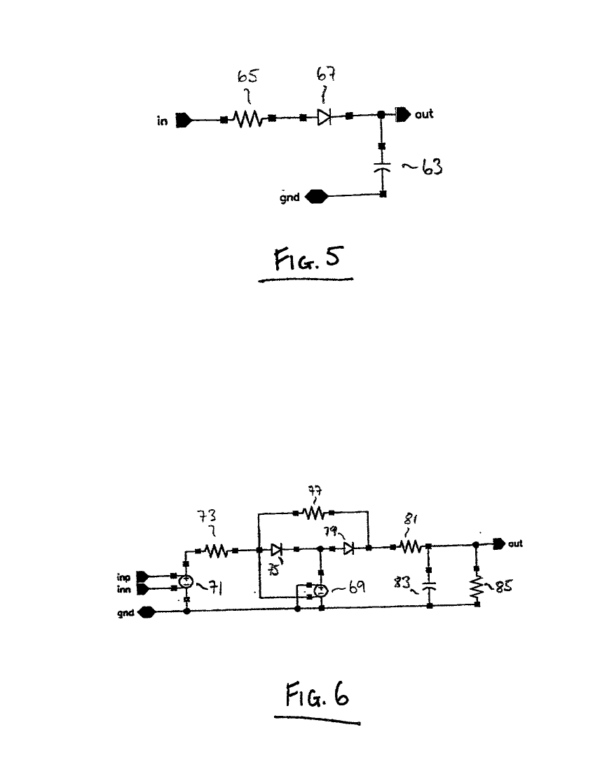

FIG. 6 shows an alternative circuit for determining the peak amplitude of the I and Q signals, and is also known in the art. The circuit of FIG. 6 has the advantage of being more sensitive, and is capable of detecting smaller signals than that of FIG. 5, (i.e. below the diode voltage drop). It is noted that the voltage controlled voltage source 69 may be replaced by an operational amplifier.

Although two alternative circuits for determining the peak amplitude have been shown in FIGS. 5 and 6, other circuits for measuring the peak amplitude may also be used without departing from the scope of the invention. For example, amplitude detectors using quadratic function circuits may be used.

Furthermore, any small residual errors still present in the amplitudes of the output signals may be corrected by adding a limiter stage to the RC phase shifter. Since only a small amplitude error is to be corrected, the limiter can have a limited gain or power consumption, thereby avoiding the disadvantages mentioned above in relation to limiter circuits.

Alternatively, any error residual errors may be removed by adding an RC poly-phase filter section, having a small Si-area, for example after the tunable phase shifter and before the following stages (i.e. mixer).

Although the embodiment described above uses the amplitude difference to tune the phase-shifter in the LO path, the tuning signal 39 may also be used to tune a phase shifter provided in the IF path.

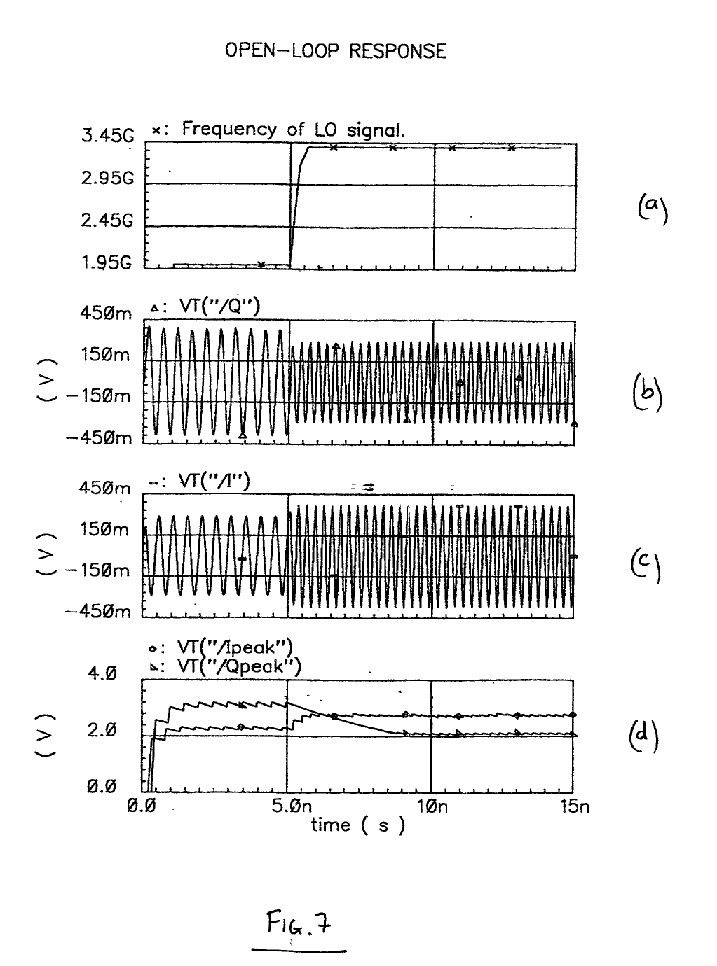

FIG. 7 shows the response of an open-loop simulation, ie. without the feedback circuitry of the present invention. As can be seen, as the frequency changes from 2.0 to 3.4 GHz in FIG. 7a, the amplitude of the I and Q signals change accordingly, (as shown in FIGS. 7c and 7b respectively). Without any feedback to tune the RC phase shifter, the amplitudes of the I and Q signals remain different, as shown in FIG. 7d, thereby reducing the effect of the image rejection circuitry.

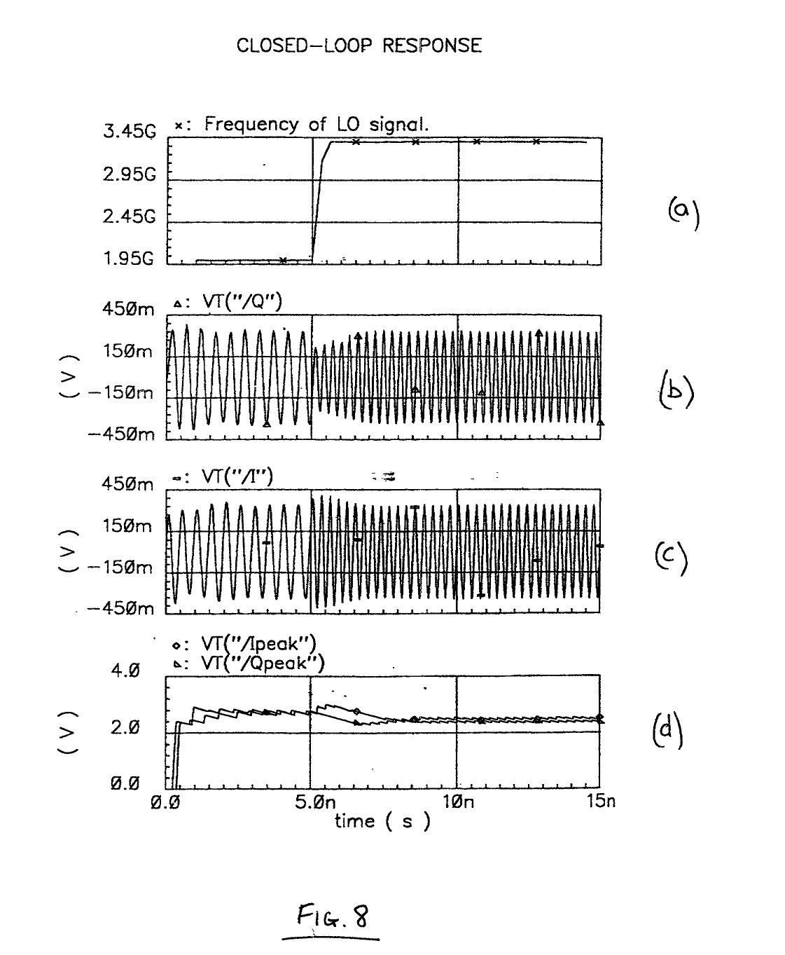

FIG. 8 shows the response of the preferred embodiment shown in FIG. 3, in which the tuning signal from the comparison of the peak detectors is fed back to the RC phase shifter. As the frequency changes from 2.0 to 3.4 GHz, (as shown in FIG. 8a), the amplitudes of the I and Q signals initially become different. However, this change is detected by the amplitude detectors, and used to tune the RC phase shifter such that the amplitudes of the I and Q signals become equal once more, as shown in FIG. 8d.

According to the embodiment described above, the absolute accuracy of the amplitude detectors per se are not important, provided that the two amplitude detectors (one for the I branch and one for the Q branch) are matched. Similarly, the performance of the embodiment described above is not significantly degraded if the detection efficiency of the peak detectors is frequency dependent, as long as the two devices are matched.

Although the invention described above has been concerned with eliminating differences between the amplitudes of the output I and Q signals, the invention could equally be applied in situations where it is desired to introduce an amplitude difference to compensate for amplitude errors found elsewhere in the system, for example, to compensate for amplitude errors in the mixer conversion gains and/or in the IF-gain stages.

For example, in some systems, the gain of the I-mixer and the Q-mixer or an I_IF-phase shifter and a Q_IF-phase shifter are different. For example, when an all-pass phase shifter is used, the I_IF-phase shifter has a 45° phase shift (R=600Ω, C=1 pF, f=100 MHZ) and the Q_IF-phase shifter uses R=3840Ω, C=1 pF, f=100 MHZ. This gives different loading of the previous or following stages which in turn give gain differences between the I or Q path. Such differences may be corrected by purposely making the gain of the first and second peak detectors slightly different.

Alternatively, the subtracting circuit (37 in FIG. 3) may be given a slightly different gain for the two inputs, i.e. 1:1.1 or 1:0.9 instead of 1:1.

The image reject circuitry described above may be implemented as an integrated circuit, for example using CMOS, BiCMOS, SiGe, or GaAs technology.

Various modifications which are obvious to those skilled in the art may be made without departing from the scope of the invention as defined by the appended claims. For example, resistors 51 and 53 of FIG. 4 may be replaced by inductors, or a combination of inductors and resistors.

1. An image reject circuit comprising:
a local oscillator for producing a local oscillator signal;
a tunable phase shifting network for receiving the local oscillator signal and producing an output in-phase (I) signal and an output quadrature (Q) signal;
first amplitude detector for determining the amplitude of the output I signal;
a second amplitude detector for determining the amplitude of the output Q signal; and,
means for determining the difference between the amplitudes of the output I and Q signals, to produce a tuning signal for tuning the phase shifting network to bring the difference between the amplitudes of the output I and Q signals towards a desired level.

2. An image reject circuit as claimed in claim 1, wherein the phase shifting network has first and second input terminals for receiving the local oscillator signal, and comprises:
a first phase shifting circuit connected between the first input terminal and a voltage reference;
a second phase shifting circuit connected between the voltage reference and the second input terminal;
first and second pairs of complementary output lines connected to each of the first and second phase shifting circuits; and,
a tuning input for receiving a tuning signal.

3. An image reject circuit as claimed in claim 2, wherein each of the first and second phase shifting circuits comprises a bridge circuit, each bridge circuit comprising:
first and second parallel arms connected between the respective input terminal and the voltage reference;
the first arm comprising a resistive element connected in series with a capacitive element;
the second arm comprising a capacitive element connected in series with a resistive element; and,
each I and Q output line being connected to a respective junction between the series connected resistive element and capacitive element.

4. An image reject circuit as claimed in any one of claims 1 to 3, wherein the phase shifting network is tuned by adjusting an RC time constant.

5. An image reject circuit as claimed in claim 4, wherein the capacitive element comprises a reverse polarity junction diode, which is tuned in accordance with the tuning signal.

6. An image reject circuit as claimed in claim 4, wherein the resistive element comprises a variable resistor, which is tuned in accordance with the tuning signal.

7. An image reject circuit as claimed in claim 4, wherein the resistive element comprises a variable resistor, the capacitive element comprises a reverse polarity junction diode, both of which are tuned in accordance with the tuning signal.

8. An image reject circuit as claimed in claim 6 or 7, wherein the resistive element comprises a MOSFET operated in its triode region.

9. An image reject circuit as claimed in claim 2, wherein each of the first and second phase shifting circuits comprises a bridge circuit, each bridge circuit comprising:
first and second parallel arms connected between the respective input terminal and the voltage reference;
the first arm comprising a resistive element connected in series with an inductive element;
the second arm comprising an inductive element connected in series with a resistive element;
each I and Q output line being connected to a respective junction between the series connected resistive element and inductive element;
wherein the phase shifting network is tuned by adjusting the RL time constant.

10. An image reject circuit as claimed in claim 2, wherein each of the first and second phase shifting circuits comprises a bridge circuit, each bridge circuit comprising:
first and second parallel arms connected between the respective input terminal and the voltage reference;
the first arm comprising an inductive element connected in series with a capacitive element;
the second arm comprising a capacitive element connected in series with an inductive element;
each I and Q output line being connected to a respective junction between the series connected inductive element and capacitive element;
wherein the phase shifting network is tuned by adjusting the LC time constant.

11. An image reject circuit as claimed in any one of claims 1 to 10, wherein the first and second amplitude detectors comprise:
an input terminal for receiving the input signal;
a resistor and forward polarity diode connected between the input terminal and an output terminal; and,
a capacitor connected between the output terminal and ground.

12. An image reject circuit as claimed in any one of claims 1 to 10, wherein the first and second amplitude detectors each comprise a two stage amplitude detector.

13. An image reject circuit as claimed in any one of claims 1 to 10, wherein the amplitude detectors include a quadratic function circuit.

14. An image reject circuit as claimed in any one of the preceding claims, wherein the desired difference between the amplitudes of the output I and Q signals is substantially zero.

15. An image reject circuit as claimed in claim 14, further comprising a limiting stage for removing any residual difference between the amplitudes of the I and Q signals.

16. An image reject circuit as claimed in claim 14 or 15, further comprising an RC poly-phase filter section for removing any residual difference between the amplitudes of the I and Q signals.

17. An image reject circuit as claimed in any one of claim 1 to 13, wherein the desired difference between the amplitudes of the output I and Q signals is set to a predetermined level, to compensate for an amplitude error found elsewhere in the system.

18. An image reject circuit as claimed in any one of the preceding claims, wherein the circuitry is implemented in bipolar technology.

19. An image reject mixer as claimed in any one of claims 1 to 17, wherein the circuitry is implemented in CMOS, BiCMOS, SiGe or GaAs technology.

20. An image reject circuit as claimed in any one of the preceding claims, wherein the circuit is implemented as an integrated circuit.

21. An image reject circuit as claimed in any preceding claim, further comprising a second tunable phase shifting network located in an intermediate frequency path, the tuning signal of the first phase shifting network also being used to tune the second phase shifting network.

22. A method of rejecting images in a receiver circuit comprising a local oscillator for producing a local oscillator signal, and a tunable phase shifting network for receiving the local oscillator signal and producing an output in-phase (I) signal and an output quadrature (Q) signal, the method comprising the steps of;
determining the amplitude of the output I signal;
determining the amplitude of the output Q signal;
determining the difference between the amplitudes of the output I and Q signals, to produce a tuning signal; and,
using the tuning signal to tune the phase shifting network to bring the difference between the amplitudes of the output I and Q signals towards a desired level.

23. A method as claimed in claim 22, wherein the phase shifting network is tuned by adjusting an RC time constant of the phase shifting network.

24. A method as claimed in claim 23, wherein the RC time constant is changed by changing the voltage across junction diodes, the change in voltage causing the capacitance of the junction diodes to change accordingly.

25. A method as claimed in claim 23, wherein the RC time constant is changed by changing the resistance value of a variable resistor

26. A method as claimed in claims 23, wherein the RC time constant is changed by changing the capacitance value and the resistance value.

27. A method as claimed in claim 25 or 26, wherein the resistance value is changed by operating a MOSFET in its triode region.

28. A method as claimed in claim 22, wherein the phase shifting network is tuned by adjusting an RL time constant of the phase shifting network.

29. A method as claimed in claim 22, wherein the phase shifting network is tuned by adjusting an LC time constant of the phase shifting network.

30. A method as claimed in any one of claims 22 to 29, wherein the amplitudes of the I and Q signals are determined using amplitude detectors.

31. A method as claimed in any one of claims 22 to 30, in which the receiver further comprises a second tunable phase shifting network located in an intermediate frequency path, the method comprising the further step of tuning the second phase shifting network according to the tuning signal determined for the first phase shifting network.

32. A method as claimed in any one of claims 22 to 31, wherein the phase shifting network is tuned such that the desired difference between the amplitudes of the I and Q signals is substantially zero.

33. A method as claimed in any one of claims 22 to 32, wherein the phase shifting network is tuned such that the desired difference between the amplitudes of the output I and Q signals is set to a predetermined level, to compensate for an amplitude error found elsewhere in the system.

34. A tunable phase shifting network for use in an image reject circuit, the tunable phase shifting network comprising:
first and second input terminals for receiving an input signal;
a first phase shifting circuit connected between the first input terminal and a voltage reference;
a second phase shifting circuit connected between the voltage reference and the second input terminal;
wherein each phase shifting circuit comprises:
first and second parallel arms connected between the respective input terminal and the voltage reference;
the first arm comprising a resistive element connected in series with a capacitive element;
the second arm comprising a capacitive element connected in series with a resistive element; and,
I and Q output lines being connected to respective junctions between the series connected resistive element and capacitive element; and,
wherein the phase shifting network further comprises a tuning input for receiving a tuning signal for adjusting an RC time constant of the phase shifting network.

35. A tunable phase shifting network as claimed in claim 34, wherein the capacitive element comprises a reverse polarity junction diode, which is tuned in accordance with the tuning signal.

36. A tunable phase shifting network as claimed in claim 34, wherein the resistive element comprises a variable resistor, which is tuned in accordance with the tuning signal.

37. A tunable phase shifting network as claimed in claim 34, wherein the resistive element comprises a variable resistor, the capacitive element comprises a reverse polarity junction diode, both of which are tuned in accordance with the tuning signal.

38. A tunable phase shifting network as claimed in claim 36 or 37, where in the resistive element comprises a MOSFET operated in its triode region.

39. A tunable phase shifting network for use in an image reject circuit, the tunable phase shifting network comprising:
first and second input terminals for receiving an input signal;
a first phase shifting circuit connected between the first input terminal and a voltage reference;
a second phase shifting circuit connected between the voltage reference and the second input terminal;
wherein each phase shifting circuit comprises:
first and second parallel arms connected between the respective input terminal and the voltage reference;
the first arm comprising a resistive element connected in series with an inductive element;
the second arm comprising an inductive element connected in series with a resistive element; and,
I and Q output lines being connected to respective junctions between the series connected resistive element and inductive element; and,
wherein the phase shifting network further comprises a tuning input for receiving a tuning signal for adjusting an RL time constant of the phase shifting network.

40. A tunable phase shifting network for use in an image reject circuit, the tunable phase shifting network comprising:
first and second input terminals for receiving an input signal;
a first phase shifting circuit connected between the first input terminal and a voltage reference;
a second phase shifting circuit connected between the voltage reference and the second input terminal;
wherein each phase shifting circuit comprises:
first and second parallel arms connected between the respective input terminal and the voltage reference;
the first arm comprising an inductive element connected in series with a capacitive element;
the second arm comprising a capacitive element connected in series with an inductive element; and,
I and Q output lines being connected to respective junctions between the series connected inductive element and capacitive element; and,
wherein the phase shifting network further comprises a tuning input for receiving a tuning signal for adjusting an LC time constant of the phase shifting network.
